(19) United States
(12) Patent Application Publication
(10) Pub. No.: US 2025/0261468 A1
(43) Pub. Date: Aug. 14, 2025

(54) IMAGE SENSOR

(71) Applicant: SAMSUNG ELECTRONICS CO., LTD., Suwon-si (KR)

(72) Inventors: CHONGKWANG CHANG, Suwon-si (KR); DONGHOON KHANG, Suwon-si (KR); KWANGYOUNG OH, Suwon-si (KR); YOUNGJAE SON, Suwon-si (KR)

(73) Assignee: SAMSUNG ELECTRONICS CO., LTD., Suwon-si (KR)

(21) Appl. No.: 18/894,331

(22) Filed: Sep. 24, 2024

(30) Foreign Application Priority Data
Feb. 8, 2024 (KR) 10-2024-0019723

(51) Int. Cl. H01L 27/146

(52) U.S. Cl. CPC H10F 39/807; H10F 39/802; H10F 39/8053; H10F 39/8057; H10F 39/8063

(57) ABSTRACT

An image sensor includes a gate electrode on a first surface of a substrate; a photoelectric conversion region in a pixel region among the plurality of pixel regions; and a deep device isolation pattern extending around the plurality of pixel region, The deep device isolation pattern includes a vertical portion with a lowermost portion; an uppermost portion; a central portion; a lower middle portion; and an upper middle portion. A ratio of a width of the uppermost portion to a width of the central portion is between 1:0.9 and 1:1.1. The deep device isolation pattern is spaced apart from the first surface of the substrate.

### CROSS-REFERENCE TO RELATED APPLICATION

This U.S. non-provisional patent application claims priority under 35 U.S.C. § 119 to Korean Patent Application No. 10-2024-0019723, filed on Feb. 8, 2024,in the Korean Intellectual Property Office, the disclosure of which is hereby incorporated by reference in its entirety.

### BACKGROUND

The present disclosure relates to an image sensor, and more specifically relates to a complementary metal-oxide semiconductor (CMOS) image sensor.

An image sensor is a device that converts optical images into electrical signals. With increased development of the computer and communications industries, there may be an increased demand for high performance image sensors that may be used for capturing images in a variety of applications such as digital cameras, camcorders, personal communication systems (PCS), gaming machines, security cameras, and/or micro-cameras for medical applications.

Image sensors may include CMOS image sensors and charge coupled devices (CCD). CMOS image sensors operate may be integrated with signal processing circuits on a single chip, thus enabling products that include the CMOS image sensors to be scaled down. In addition, CMOS image sensors may operate with relatively low power consumption. Thus, CMOS image sensors are applicable to portable electronic devices. Furthermore, CMOS image sensors may be fabricated using CMOS fabrication techniques, which may reduce manufacturing complexity. Moreover, CMOS image sensors may provide high resolution images. Accordingly, the use of CMOS image sensors has increased.

### SUMMARY

One or more embodiments provide an image sensor with improved reliability.

According to an aspect of an embodiment, an image sensor includes: a substrate including a first surface, a second surface and a plurality of pixel regions between the first surface and the second surface; a gate electrode on the first surface; a photoelectric conversion region in a pixel region among the plurality of pixel regions; and a deep device isolation pattern extending around the plurality of pixel region. The deep device isolation pattern includes a horizontal portion parallel to the first surface of the substrate and a vertical portion extending from the horizontal portion toward the first surface of the substrate. The vertical portion of the deep device isolation pattern includes: a lowermost portion at a lowermost surface of the vertical portion; an uppermost portion at an uppermost surface of the vertical portion; a central portion between the lowermost portion and the uppermost portion; a lower middle portion between the lowermost portion and the central portion; and an upper middle portion between the uppermost portion and the central portion. A ratio of a width of the uppermost portion to a width of the central portion is between 1:0.9 and 1:1.1. The deep device isolation pattern is spaced apart from the first surface of the substrate.

According to another aspect of an embodiment, an image sensor includes: a substrate including a first surface in contact with a gate electrode, a second surface facing the first surface and a plurality of pixel regions; a photoelectric conversion region in a pixel region among the plurality of pixel regions; and a deep device isolation pattern extending around the pixel region. The deep device isolation pattern includes: a horizontal portion parallel to the first surface of the substrate; and a vertical portion in a vertical trench extending from the horizontal portion toward the first surface of the substrate. A sidewall of the vertical trench is perpendicular to the first surface of the substrate, and a depth of the vertical trench is less than a thickness of the substrate.

According to another aspect of an embodiment, an image sensor includes: a substrate including a first surface, a second surface and a plurality of pixel regions between the first surface and the second surface; a gate electrode on the first surface of the substrate and extending into the substrate; a photoelectric conversion region in a pixel region among the plurality of pixel regions; a floating diffusion region in the pixel region that is spaced apart from the photoelectric conversion region; and a deep device isolation pattern extending around the pixel region. The deep device isolation pattern includes: a horizontal portion parallel to the first surface of the substrate; and a vertical portion in a vertical trench extending from the horizontal portion toward the first surface of the substrate. The vertical portion of the deep device isolation pattern includes: a lowermost portion at a lowermost surface of the vertical portion; an uppermost portion at an uppermost surface of the vertical portion; a central portion between the lowermost portion and the uppermost portion; a lower middle portion between the lowermost portion and the central portion; and an upper middle portion between the uppermost portion and the central portion. A ratio of a width of the uppermost portion to a width of the central portion is between 1:0.9 and 1:1.1. The deep device isolation pattern is spaced apart from the first surface of the substrate.

### BRIEF DESCRIPTION OF DRAWINGS

The above and other aspects and features will be apparent from the following description of embodiments, taken in conjunction with the accompanying drawings. The accompanying drawings represent non-limiting, example embodiments as described herein.

FIG. 1 is a block diagram for explaining an image sensor according to embodiments.

FIG. 2 is a circuit diagram of a unit pixel of an image sensor according to embodiments.

FIG. 3 is a plan view of an image sensor according to embodiments.

FIG. 4 is a cross-sectional view taken along line A-A′ in FIG. 3.

FIG. 5 is an enlarged view of ‘X’ in FIG. 3.

FIG. 6 is a cross-sectional view for explaining an image sensor according to embodiments, and corresponds to a cross-section taken along line A-A′ in FIG. 3.

FIGS. 7 to 10 are cross-sectional views corresponding to line A-A′ of FIG. 3 illustrating a method of manufacturing an image sensor according to embodiments.

FIG. 11 is a cross-sectional view for explaining an image sensor according to embodiments, and corresponds to a cross-section taken along line A-A′ in FIG. 3.

FIG. 12 is a cross-sectional view for explaining an image sensor according to embodiments, and corresponds to a cross-section taken along line A-A′ in FIG. 3.

### DETAILED DESCRIPTION

Hereinafter, embodiments are described in detail with reference to the accompanying drawings. Like components are denoted by like reference numerals throughout the specification, and repeated descriptions thereof are omitted. It will be understood that when an element or layer is referred to as being “on,” “connected to” or “coupled to” another element or layer, it can be directly on, connected or coupled to the other element or layer, or intervening elements or layers may be present. By contrast, when an element is referred to as being “directly on,” “directly connected to” or “directly coupled to” another element or layer, there are no intervening elements or layers present. Embodiments described herein are example embodiments, and thus, the present disclosure is not limited thereto, and may be realized in various other forms. Each embodiment provided in the following description is not excluded from being associated with one or more features of another example or another embodiment also provided herein or not provided herein but consistent with the present disclosure.

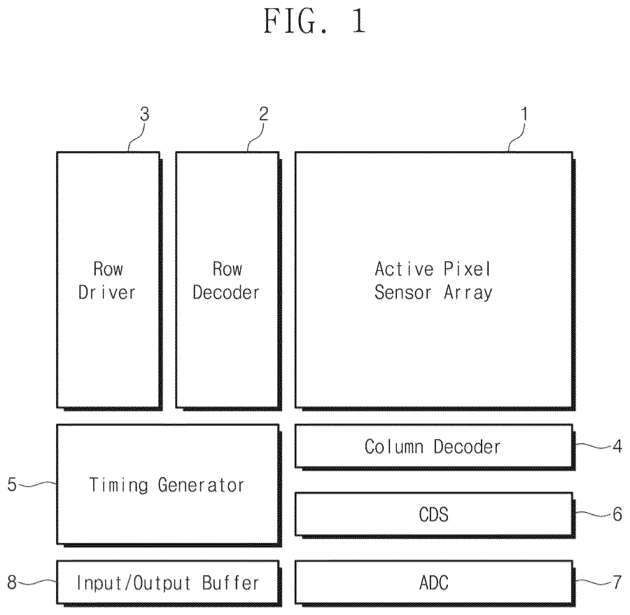

FIG. 1 is a block diagram for explaining an image sensor according to embodiments.

Referring to FIG. 1, an image sensor may include an active pixel sensor array 1, a row decoder 2, a row driver 3, a column decoder 4, a timing generator 5, a correlated double sampler (CDS) 6, an analog-to-digital converter (ADC) 7, and an input/output (I/O) buffer 8.

The active pixel sensor array 1 may include a plurality of two-dimensionally arranged unit pixels, each of which is configured to convert optical signals into electrical signals. The active pixel sensor array 1 may be driven by a plurality of driving signals such as a pixel selection signal, a reset signal, and a charge transfer signal from the row driver 3. Additionally, the correlated double sampler 6 may be provided with the converted electrical signals.

The row driver 3 may provide the active pixel sensor array 1 with several of the driving signals for driving several unit pixels in accordance with a decoded result obtained from the row decoder 2. When the unit pixels are arranged in a matrix shape, the driving signals may be provided for respective rows.

The timing generator 5 may provide timing and control signals to the row decoder 2 and the column decoder 4.

The correlated double sampler 6 may receive the electrical signals generated from the active pixel sensor array 1, and may hold and sample the received electrical signals. The correlated double sampler 6 may perform a double sampling operation to sample a specific noise level and a signal level of the electrical signal, and outputs a difference level corresponding to a difference between the noise and signal levels.

The analog-to-digital converter 7 may convert analog signals, which correspond to the difference level received from the correlated double sampler 6, into digital signals, and may output the converted digital signals.

The input/output buffer 8 may latch the digital signals and then may sequentially output the latched digital signals to an image signal processing unit in response to the decoded result obtained from the column decoder 4.

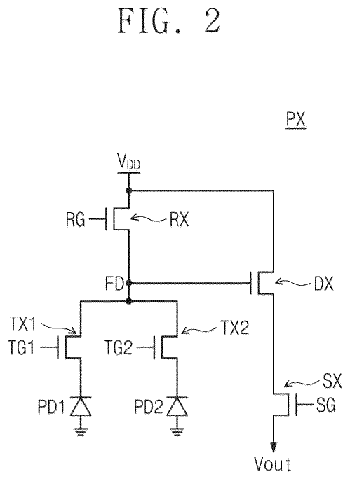

FIG. 2 is a circuit diagram of a unit pixel of an image sensor according to embodiments.

Referring to FIGS. 1 and 2, the active pixel sensor array 1 may include a plurality of unit pixels PX, which may be arranged in a matrix shape. Each of the unit pixels PX may include a first photoelectric conversion element PD1, a second photoelectric conversion element PD2, a first transfer transistor TX1, a second transfer transistor TX2, and logic transistors RX, SX, and DX. The logic transistors RX, SX, and DX of FIG. 2 include a reset transistor RX, a selection transistor SX, and a drive transistor DX. The first transfer transistor TX1, the second transfer transistor TX2, the reset transistor RX, and the selection transistor SX may include a first transfer gate TG1, a second transfer gate TG2, a reset gate RG, and a selection gate SG, respectively. Each of the pixels PX may further include a floating diffusion region FD.

The first and second photoelectric conversion elements PD1 and PD2 may generate and accumulate charges in proportion to the amount of light incident thereon (i.e., light from the outside). The first and second photoelectric conversion elements PD1 and PD2 may be photodiodes including a P-type impurity region and an N-type impurity region. The first transfer transistor TX1 may transmit charges generated in the first photoelectric conversion element PD1 to the floating diffusion region FD, and the second transfer transistor TX2 may transmit the charges generated in the first photoelectric conversion element PD1 to the floating diffusion region FD.

The floating diffusion region FD may receive charges generated in the first and second photoelectric conversion elements PD1 and PD2 and store the charges cumulatively. The drive transistor DX may be controlled depending on the amount of charges accumulated in the floating diffusion region FD.

The reset transistor RX may periodically reset charges accumulated in the floating diffusion region FD. The drain electrode of the reset transistor RX may be connected to the floating diffusion region FD, and the source electrode of the reset transistor RX may be connected to the power supply voltage VDD. When the reset transistor RX is turned on, a power supply voltage VDD connected to the source electrode of the reset transistor RX may be applied to the floating diffusion region FD. Accordingly, when the reset transistor RX is turned on, charges accumulated in the floating diffusion region FD may be discharged and the floating diffusion region FD may be reset.

The drive transistor DX may function as a source follower buffer amplifier. The drive transistor DX may amplify the potential change in the floating diffusion region FD and output the potential change to a output line Vout.

The selection transistor SX may select pixels PX to be read row by row. When the selection transistor SX is turned on, the power supply voltage VDD may be applied to a drain electrode of the drive transistor DX.

Although FIG. 2 illustrates the unit pixel PX having two photoelectric conversion elements PD1 and PD2 and five transistors TX1, TX2, RX, DX, and SX, embodiments are not limited thereto. For example, the reset transistor RX, the drive transistor DX, or the selection transistor SX may be shared by neighboring pixels PX. Accordingly, integration of the image sensor may be improved.

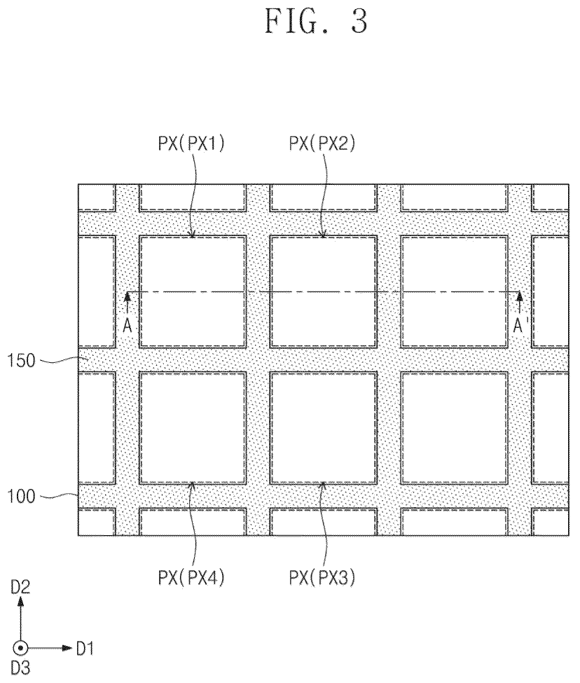

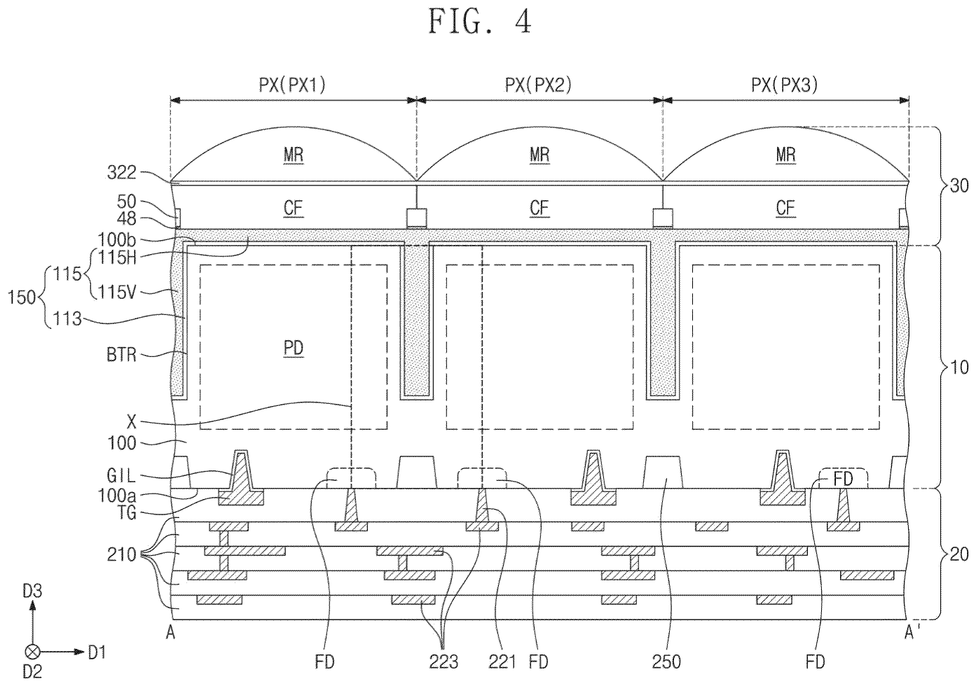

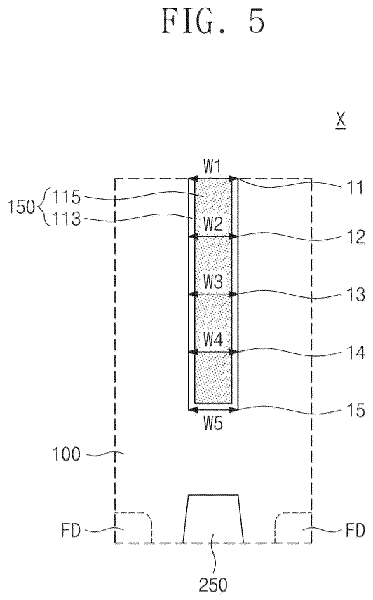

FIG. 3 is a plan view of an image sensor according to embodiments. FIG. 4 is a cross-sectional view taken along line A-A′ in FIG. 3. FIG. 5 is an enlarged view of ‘X’ in FIG. 3.

Referring to FIGS. 3, 4, and 5, an image sensor according to embodiments may include a photoelectric conversion layer 10, a wiring layer 20, and a light transmission layer 30. The photoelectric conversion layer 10 may be disposed between the wiring layer 20 and the light transmission layer 30.

The photoelectric conversion layer 10 may include a substrate 100, and the substrate 100 may include a plurality of pixel regions PX. The substrate 100 may be a semiconductor substrate (e.g., a silicon substrate, a germanium substrate, a silicon-germanium substrate, a group II-VI compound semiconductor substrate, or a group III-V compound semiconductor substrate) or a silicon on insulator (SOI) substrate. The substrate 100 may have a first surface 100a and a second surface 100b facing each other. The plurality of pixel regions PX may be two-dimensionally arranged in a first direction D1 and a second direction D2. The first direction DI and the second direction D2 may intersect each other and may be parallel to the first surface 100a of the substrate 100. The first surface 100a of the substrate 100 may be in contact with the gate electrode TG, and light may be incident on the second surface 100b of the substrate 100. That is, light may be incident from the second surface 100b of the substrate 100 and transmitted to the pixel region.

In one embodiment, the first photoelectric conversion region PD may be disposed in a first pixel region PX1, and the second photoelectric conversion region PD may be disposed in a second pixel region PX2. The first pixel region PX1 and the second pixel region PX2 may be adjacent to each other in the first direction D1. The first photoelectric conversion region PD1 and the second photoelectric conversion region PD2 may be adjacent to each other in the first direction D1. A third pixel region PX3 may be arranged to be spaced apart from the second pixel region PX2 in the second direction D2. A fourth pixel region PX4 may be arranged to be spaced apart from the third pixel region PX3 in the first direction D1. The third photoelectric conversion region PD3 may be in the third pixel region PX3, and the fourth photoelectric conversion region PD4 may be in the fourth pixel region PX4. FIG. 4 shows that the first to fourth photoelectric conversion regions PD are arranged in a clockwise direction, but this is only for convenience of explanation and embodiments are not limited thereto. A deep device isolation pattern 150 may be disposed between the first photoelectric conversion region PD1 and the second photoelectric conversion region PD2. Light incident from the outside may be converted into an electrical signal in the photoelectric conversion regions PD. The photoelectric conversion region PD may be an impurity region having a second conductivity type different from the first conductivity type of the semiconductor substrate 100. The photoelectric conversion region PD may have an impurity concentration difference between the first region adjacent to the first surface 100a and the second region adjacent to the second surface 100b.

The photoelectric conversion layer 10 may further include a deep isolation pattern 150 disposed between the plurality of pixel regions PX. The deep device isolation pattern 150 may extend from the second surface 100b of the substrate 100 toward the first surface 100a of the substrate. The deep device isolation pattern 150 may extend from the second surface 100b of the substrate toward the inside of the substrate. A lower surface of the deep device isolation pattern 150 may be interposed in the substrate. For example, the lower surface of the deep device isolation pattern 150 may be provided between the first surface 100a and the second surface 100b of the substrate. The deep device isolation pattern 150 may prevent cross-talk between neighboring pixel regions PX.

The deep device isolation pattern 150 may surround each of the plurality of pixel regions PX when viewed in a plan view. The deep device isolation pattern 150 may define a plurality of pixel regions PX. The deep device isolation pattern 150 may extend to surround each pixel region PX in the first direction D1 and the second direction D2.

The deep device isolation pattern 150 may include a semiconductor pattern 115 and an insulating pattern 113 interposed between the semiconductor pattern 115 and the substrate. The semiconductor pattern 115 may penetrate a portion of the semiconductor substrate 100 in a third direction D3.

The deep device isolation pattern 150 may include an insulating pattern 113 conformally covering the vertical trench BTR and the second surface 100b of the substrate 100, and a semiconductor pattern 115 provided on the insulating pattern 113 and filling the vertical trench BTR. The insulating pattern 113 may be provided between the semiconductor pattern 115 and the substrate 100.

For example, the insulating pattern 113 may include at least one of silicon oxide, silicon oxynitride, and silicon nitride.

The semiconductor pattern 115 may include, for example, indium tin oxide (ITO), indium zinc oxide (IZO), zinc oxide (ZnO), or an organic transparent conductive material. The semiconductor pattern 115 may include, for example, polysilicon.

The deep device isolation pattern 150 may fill the vertical trench BTR extending from the second surface 100b of the semiconductor substrate 100 toward the first surface 100a. The deep device isolation pattern 150 may cover the second surface 100b of the semiconductor substrate 100. That is, the deep device isolation pattern 150 may include a vertical portion that fills the vertical trench BTR and a horizontal portion that covers the second surface 100b of the semiconductor substrate 100. That is, the deep device isolation pattern 150 may include a horizontal portion parallel to the first surface 100a of the substrate and a vertical portion extending from the horizontal portion toward the first surface 100a of the substrate. The vertical portion of the deep device isolation pattern 150 may be disposed in the vertical trench BTR extending from the horizontal portion toward the first surface 100a of the substrate 100.

The vertical portion of the deep device isolation pattern 150 may have a substantially constant width. An inner wall of the vertical trench BTR may be perpendicular to the first surface 100a of the substrate. A sidewall of the vertical portion of the deep device isolation pattern may be perpendicular to the first surface 100a of the substrate.

A depth of the vertical trench BTR may be less than a thickness of the substrate 100. The lowermost surface of the vertical trench BTR may be spaced apart from the first surface 100a of the substrate 100. The lowermost surface of the vertical portion of the deep device isolation pattern 150 may be spaced apart from the first surface 100a of the substrate 100.

The deep device isolation pattern 150 may include an insulating material with a lower refractive index than the semiconductor substrate 100 (e.g., silicon).

Referring again to FIG. 4, the insulating pattern 113 may be provided to conformally cover the inner wall of the vertical trench BTR and the second surface 100b of the substrate 100. The semiconductor pattern 115 may be provided on the insulating pattern 113 to fill the vertical trench BTR, and the semiconductor pattern 115 may be provided on the insulating pattern 113 on the second surface 100b. In this case, the horizontal portion of the deep device isolation pattern 150 may include a horizontal portion 115H of the semiconductor pattern 115 and an insulating pattern 113 between the horizontal portion 115H of the semiconductor pattern 115 and the substrate. The vertical portion of the deep device isolation pattern 150 may include a vertical portion 115V of the semiconductor pattern 115 and an insulating pattern 113 between the vertical portion 115V of the semiconductor pattern 115 and the substrate.

An additional separation pattern 250 may be disposed adjacent to the first surface 100a of the substrate 100. The additional separation pattern 250 may define active portions on the first surface 100a of the semiconductor substrate 100 in each of the pixel regions PX. For example, the additional separation pattern 250 may include at least one of a silicon oxide layer, a silicon nitride layer, and a silicon oxynitride layer. Active portions may be spaced apart from each other in each of the pixel regions PX and may have different sizes. The additional separation pattern 250 may be interposed between the active patterns.

The additional separation pattern 250 and the vertical trench BTR may overlap vertically. The additional separation pattern 250 and the deep device isolation pattern 150 may overlap vertically. The additional separation pattern 250 may be vertically spaced apart from the deep device isolation pattern 150. A sidewall of the additional separation pattern 250 may be inclined with respect to the first surface 100a of the substrate 100. That is, a width of the additional separation pattern 250 may not be constant depending on a distance from the first surface 100a of the substrate 100. The width of the additional separation pattern 250 may gradually decrease in a direction from the first surface 100a to the second surface 100b of the substrate 100. The additional separation pattern 250 may be a silicon oxide layer, a silicon oxynitride layer, or a silicon nitride layer.

A gate electrode TG and the floating diffusion region FD may be disposed on each pixel region PX and adjacent to the first surface 100a of the substrate 100. The gate electrode TG and the floating diffusion region FD may be disposed on corresponding active portions of the active portions. The gate electrode TG may overlap the photoelectric conversion region PD vertically (e.g., in the third direction D3).

The gate electrode TG may extend into the substrate 100. At least a portion of the gate electrode TG may be provided in a vertical trench recessed from the first surface 100a of the semiconductor substrate 100. The gate electrode TG may include a lower portion inserted into the semiconductor substrate 100 and an upper portion connected to the lower portion and protruding above the first surface 100a of the semiconductor substrate 100.

The lower portion of the gate electrode TG may penetrate at least a portion of the semiconductor substrate 100. The lower portion of each of the gate electrodes TG may extend into the substrate 100 toward the photoelectric conversion region PD, and the upper portion of each of the gate electrodes TG may protrude above an upper surface of the corresponding active portion (i.e., the first surface 100a of the substrate 100).

A gate insulating layer GIL may be interposed between the gate electrodes TG and the semiconductor substrate 100.

The wiring layer 20 may include wirings (e.g., MOS transistors) connected to the photoelectric conversion layer 10. An electrical signal converted in the photoelectric conversion layer 10 may be processed in the wiring layer 20.

The wiring layer 20 may be disposed on the first surface 100a of the substrate 100. The wiring layer 20 may include interlayer insulating layers 210 sequentially stacked on the first surface 100a of the substrate 100. The interlayer insulating layer 210 may be disposed on the first surface 100a of the substrate 100 to cover the transfer gate electrode TG. The interlayer insulating layers 210 may include an insulating material. The interlayer insulating layers 210 may include, for example, at least one of silicon oxide, silicon oxynitride, and silicon nitride.

The wiring layer 20 may further include wiring structures 221 and 223 provided in the interlayer insulating layer 210. The wiring structures 221 and 223 may include metal wirings 223 and contact plugs 221 connecting the metal wirings 223. Some of the contact plugs 221 may be connected to the floating diffusion region FD. The metal wirings 223 and the contact plugs 221 may include a conductive material.

A light transmission layer 30 may be provided on the second surface 100b of the semiconductor substrate 100. The light transmission layer 30 may include light shielding patterns 48, low refractive patterns 50, color filters CF, a lens insulating layer 322, and microlenses MR. The light transmission layer 30 may collect and filter light incident from the outside and provide the light to the photoelectric conversion layer 10.

A protective layer may be additionally provided between the light transmission layer 30 and the deep device isolation pattern 150.

Light shielding patterns 48 may be disposed on the deep device isolation pattern 150. The light shielding patterns 48 may be disposed on the horizontal portion of the deep device isolation pattern 150. Low refractive patterns 50 may be respectively disposed on the light shielding patterns 48. The light shielding pattern 48 and the low refractive pattern 50 may have a grid structure defining light transmission regions that vertically overlap each of the plurality of unit pixels.

The light shielding pattern 48 and the low refractive pattern 50 overlap the deep device isolation pattern 150 and may have a two-dimensional grid shape. The light shielding pattern 48 may include titanium, for example. The low refractive patterns 50 have the same thickness and may include the same organic materials. The low refractive pattern 50 may have a refractive index less than that of the color filters CF, which will be described later. For example, the low refractive pattern 50 may have a refractive index of about 1.3 or less. The light shielding pattern 48 and the low refractive pattern 50 may prevent crosstalk between adjacent unit pixels PX.

The color filters corresponding to each of the first to second pixel regions PX1, PX2, PX3, and PX4 may be provided. As an example, a color filter CF corresponding to the first pixel region PXI may be provided in the first pixel region PX1. The same may apply to the second to fourth pixel regions PX2, PX3, and PX4.

The color filters CF may be disposed between adjacent low refractive patterns 50. The color filters CF may each have one color among blue, green, and red. As another example, the color filters CF may include other colors such as cyan, magenta, or yellow. In the image sensor according to this example, the color filters CF may be arranged in a Bayer pattern. In another example, the color filters CF may be arranged in a 2×2 array of tetra patterns, 3×3 arrays of nona patterns, or 4×4 arrays of hexadeca patterns.

A lens insulating layer 322 may be interposed between the color filters CF and the microlenses MR. The microlenses MR may be disposed on the lens insulating layer 322.

The microlenses MR may overlap with corresponding photoelectric conversion regions PD. One microlens MR may overlap with one photoelectric conversion region PD. One microlens may be disposed between two vertical portions 115V of the deep device isolation pattern 150 that are adjacent and spaced apart when viewed in a plan view.

FIGS. 4 and 5 show that the vertical portion of the deep device isolation pattern 150 in detail. The vertical portion of the deep device isolation pattern 150 may fill the vertical trench BTR. That is, the vertical portion of the deep device isolation pattern 150 may be defined as the deep device isolation pattern 150 disposed below the second surface 100b of the substrate 100. The vertical portion of the deep device isolation pattern 150 may include the vertical portion 115V of the semiconductor pattern 115 and the insulating pattern 113.

The vertical portion of the deep device isolation pattern 150 may have a height of 1.5 μm or more. The vertical portion of the deep device isolation pattern 150 may include a lowermost portion 15 defined at the lowermost surface of the vertical portion, an uppermost portion 11 defined on the uppermost surface of the vertical portion, a central portion 13 defined in a center of the vertical portion, a lower middle portion 14 defined between the lowermost portion 15 and the central portion 13, and an upper middle portion 12 defined between the uppermost portion 11 and the central portion 13. A distance between the uppermost portion 11 and the upper middle portion 12, a distance between the upper middle portion 12 and the central portion 13, a distance between the central portion 13 and the lower middle portion 14, and a distance between lower middle portion 14 and the lowermost portion 15 may be the same.

The width of the uppermost portion 11 along the first direction D1 may be W1, the width of the upper middle portion 12 along the first direction D1 may be W2, the width of the central portion 13 along the first direction DI may be W3, the width of the lower middle portion 14 along the first direction D1 may be W4, and the width of the lowermost portion 15 along the first direction D1 may be W5. The width WI of the uppermost portion 11 along the first direction D1 may be 150 nm or less. A ratio of the width WI to the width W2 may be between 1:1 and 1:1.15. A ratio of the width W2 to the width W3 may be between 1:0.9 and 1:1.1. The width W4 and the width W5 may be equal to or less than the width W1 of the uppermost portion 11.

In one embodiment, the width W1 of the uppermost portion 11, the width W2 of the upper middle portion 12, the width W3 of the central portion 13, the width W4 of the lower middle portion 14 and the width W5 of the lowermost portion 15 may all be the same.

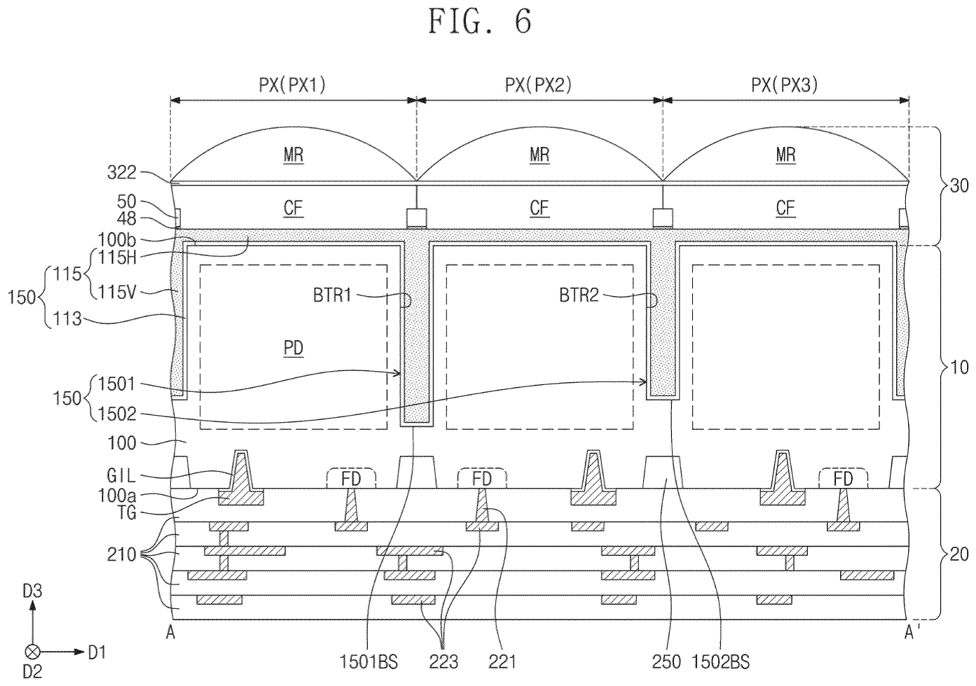

FIG. 6 is a cross-sectional view for explaining an image sensor according to embodiments, and corresponds to a cross-section taken along line A-A′ in FIG. 3. To simplify the explanation, content that overlaps with the above-described content is omitted.

Referring to FIG. 6, the deep device isolation pattern 150, that is, the vertical portion of the deep device isolation pattern 150, may include a first vertical portion 1501 and a second vertical portion 1502 adjacent to and spaced apart from the first vertical portion 1501. The first vertical portion 1501 may be provided in a first vertical trench BTR1. The second vertical portion 1502 may be provided in a second vertical trench BTR2. A depth of the first vertical trench BTR1 may be greater than a depth of the second vertical trench BTR2.

A level of the lowermost surface 1501BS of the first vertical portion 1501 may be different from a level of the lowermost lower surface 1502BS of the second vertical portion 1502. For example, the level of the lowermost surface 1501BS of the first vertical portion 1501 may be higher than the level of the lowermost surface 1502BS of the second vertical portion 1502. That is, a distance of the lowermost surface 1501BS of the first vertical portion 1501 from the first surface 100a of the substrate 100 may be less than a distance of the lowermost surface 1502BS of the second vertical portion 1502 from the first surface 100a of the substrate 100. In one example, a ratio of a length of the first vertical portion 1501 to a length of the second vertical portion 1502 may be approximately 1:0.8. When viewed in a plan view, one microlens MR may be disposed between the first vertical portion 1501 and the second vertical portion 1502.

When the deep device isolation pattern 150 is not vertical, bowing may cause a width of the deep device isolation pattern 150 to be increased. In this case, when the semiconductor pattern 115 and the insulating pattern 113 are formed in the deep device isolation pattern 150, voids may be formed therein.

When the deep device isolation pattern 150 is not vertical, bowing may cause a bowed portion to be formed, and when a doping process is performed on a sidewall of the deep device isolation pattern 150, a concentration may be higher in the bowed portion. Accordingly, full well capacity (FWC) may decrease.

According to embodiments, the deep device isolation pattern 150 may be provided in the vertical trench BTR perpendicular to the first surface 100a of the substrate 100. As the deep device isolation pattern 150 is perpendicular to the first surface 100a of the substrate 100, the bowing and voids of the deep device isolation pattern 150 may be reduced. Accordingly, the full well capacity (FWC) may increase.

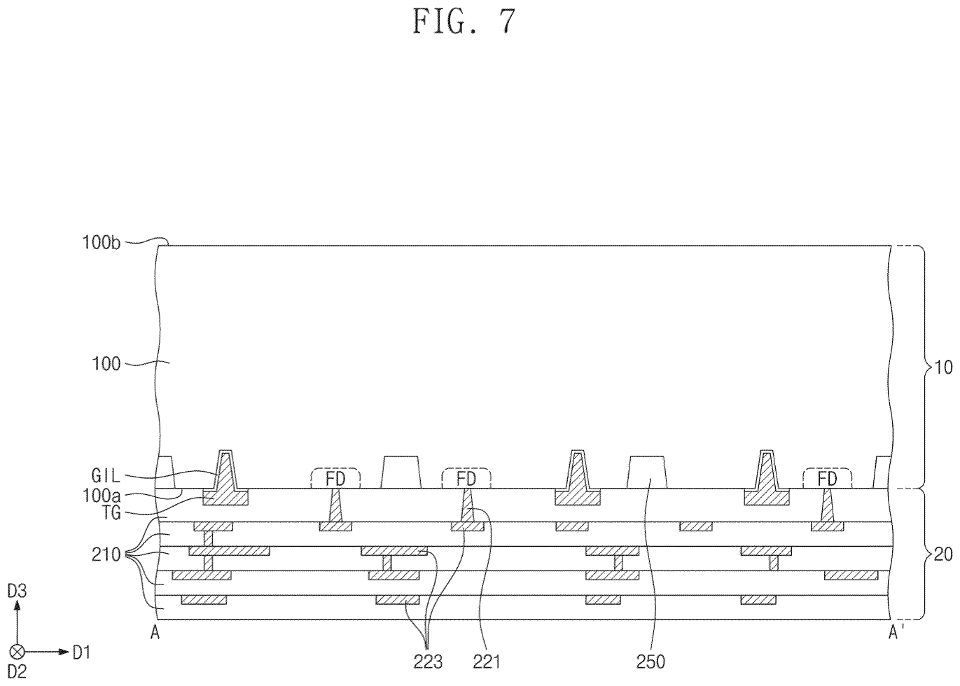

FIGS. 7 to 10 are cross-sectional views corresponding to line A-A′ of FIG. 3 illustrating a method of manufacturing an image sensor according to embodiments.

Referring to FIGS. 4 and 7, a wiring layer 20 and a semiconductor substrate 100 connected to the wiring layer 20 and a gate electrode TG may be provided. The semiconductor substrate 100 may be doped with impurities to have a first conductivity type (e.g., p-type).

An additional separation pattern 250 may be formed on the first surface 100a of the substrate 100. Forming the additional separation pattern 250 may include forming shallow trenches in the first surface 100a of the substrate 100 and filling the shallow trenches with an insulating layer. The insulating layer may be formed using silicon oxide, silicon nitride, and/or silicon oxynitride.

The additional separation patterns 250 may define activation patterns. Impurities may be doped into each of the active patterns to form a floating diffusion region FD. A gate electrode TG may be formed on the active patterns. An interlayer insulating layer 220, wirings 223, and contact plugs 221 may be formed on the first surface 100a of the substrate 100.

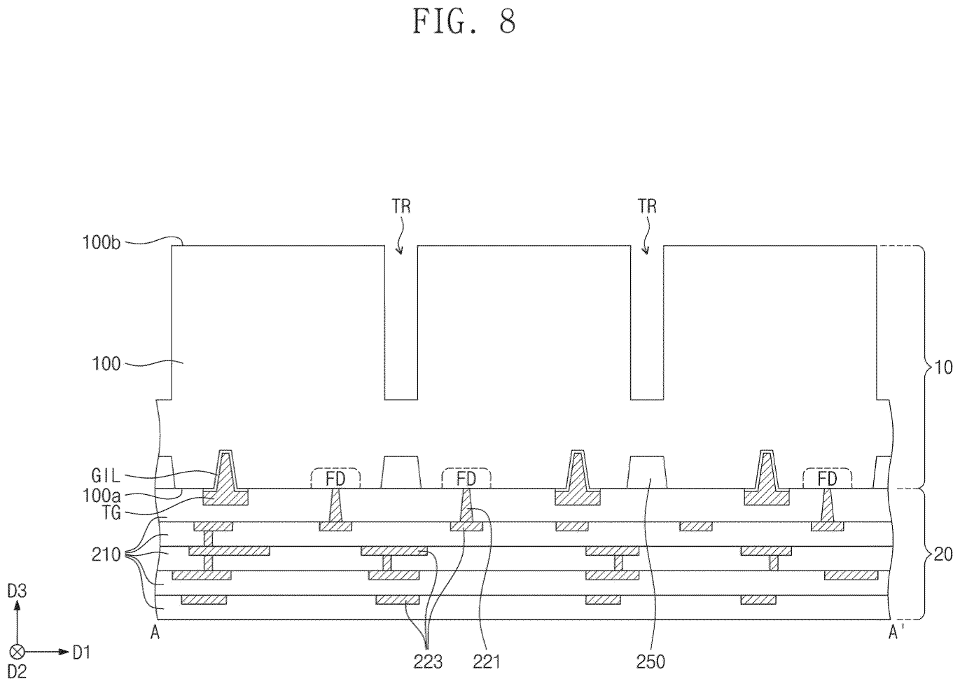

Referring to FIG. 8, an etching process may be performed on the second surface 100b of the substrate 100 to form a trench TR. A depth of the trench TR in the third direction D3 may be formed to be less than a thickness of the semiconductor substrate 100 in the third direction D3. A width of the trench TR in the first direction DI may be constant from the second surface 100b to the first surface 100a of the semiconductor substrate 100. When viewed in a plan view, the trench TR may be formed to have a lattice structure. A plurality of unit pixels PX may be defined by the trench TR. The unit pixels PX may be two-dimensionally arranged in a first direction D1 and a second direction D2 that intersect each other.

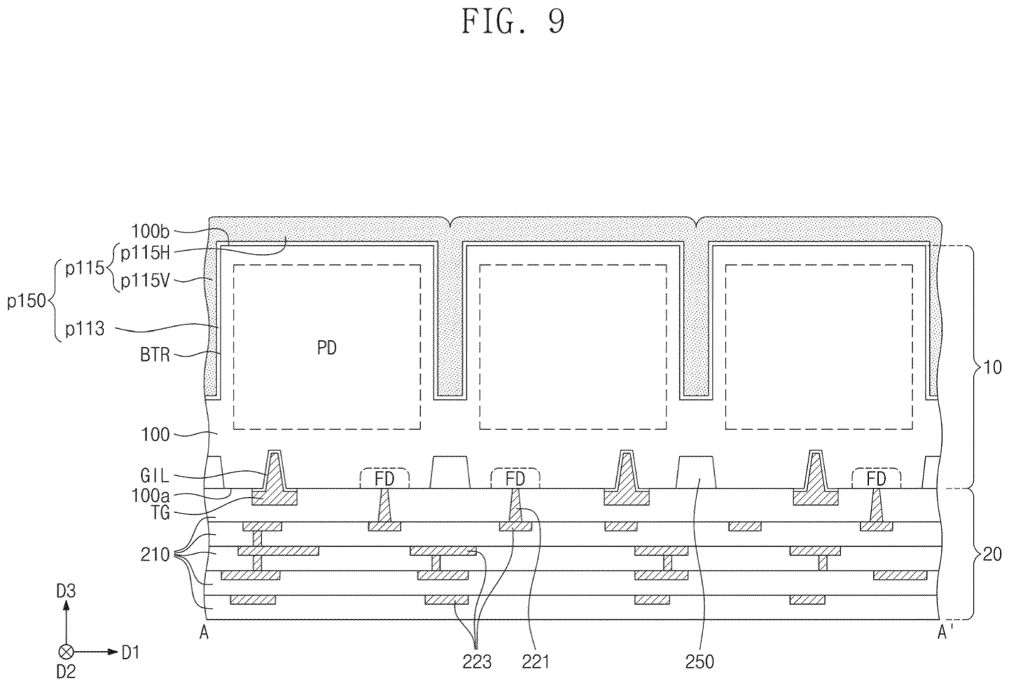

Referring to FIG. 9, a preliminary insulating pattern 113 and a preliminary semiconductor pattern p115 filling the trench TR may be sequentially formed. The preliminary insulating pattern 113 may be conformally formed to partially fill the trench TR. The trench TR may be a vertical trench BTR. The preliminary insulating pattern 113 may cover the second surface 100b of the substrate 100. A horizontal portion p115H of the preliminary semiconductor pattern p115 may be formed on the preliminary insulating pattern 113 covering the second surface 100b of the substrate 100. A vertical portion p115V of the preliminary semiconductor pattern p115 may be formed on the preliminary insulating pattern 113 that conformally covers an inner wall of the vertical trench BTR. The vertical portion p115V of the preliminary semiconductor pattern p115 may fill the vertical trench BTR.

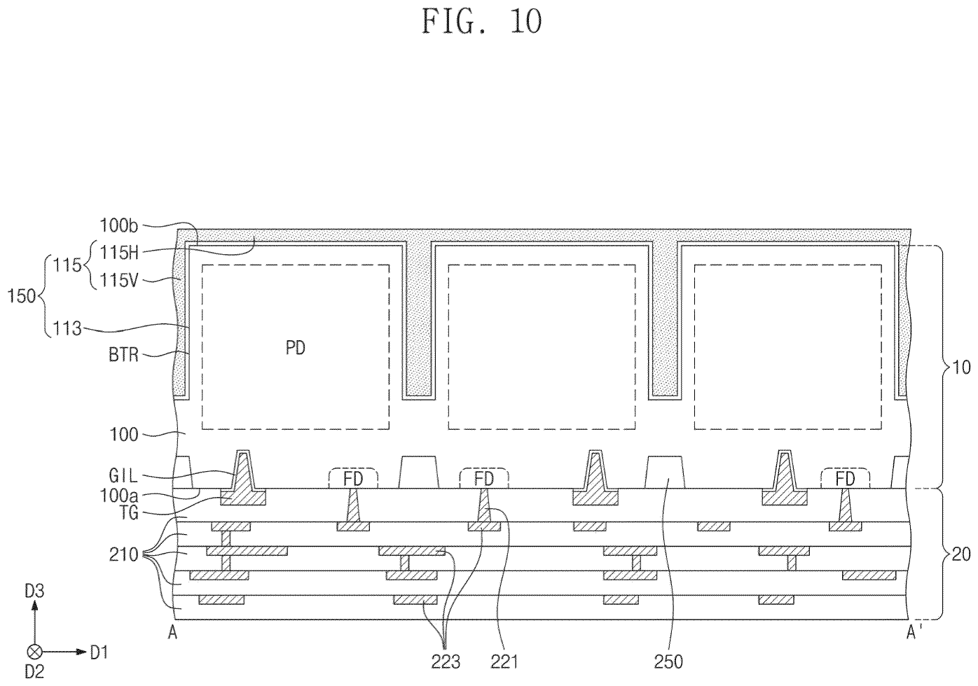

Referring to FIG. 10, an upper surface of the horizontal portion p115H of the preliminary semiconductor pattern p115 may be flattened. The upper surface of the horizontal portion p115H of the preliminary semiconductor pattern p115 may be conformal. A deep device isolation pattern 150 including a semiconductor pattern 115 and an insulating pattern 113 may be formed.

Referring again to FIGS. 4 and 10, light shielding patterns 48, low refractive patterns 50, color filters CF, lens insulating layer 322, and microlenses MR may be formed on the horizontal portion 115p of the semiconductor pattern 115. A light transmission layer 30 may be formed.

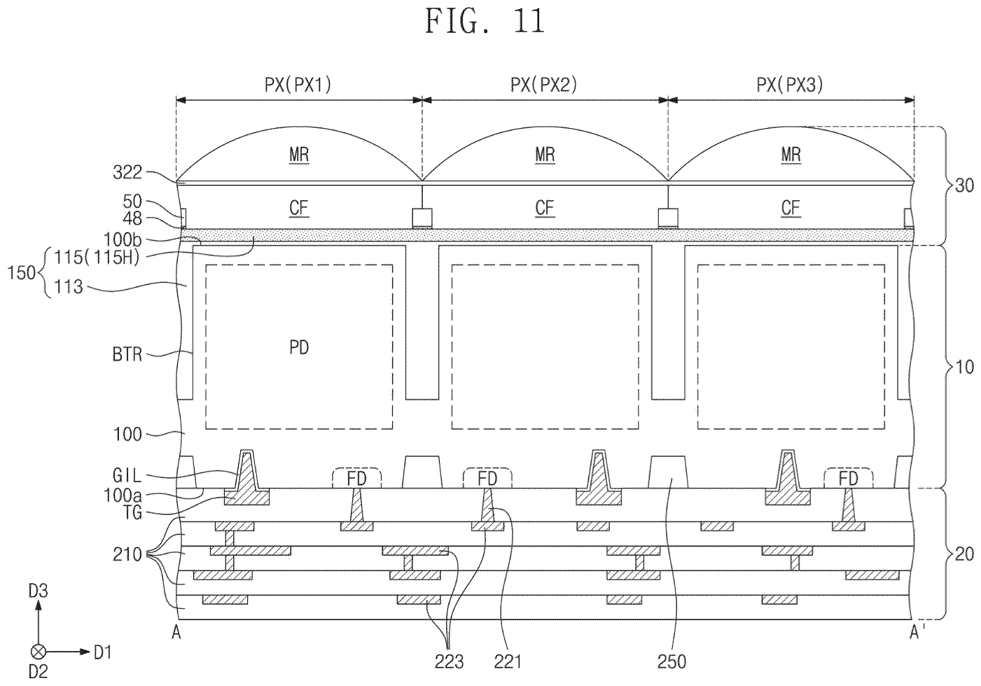

FIG. 11 is a cross-sectional view for explaining an image sensor according to embodiments, and corresponds to a cross-section taken along line A-A′ in FIG. 3. To simplify the explanation, content that overlaps with the above-described content is omitted.

Referring to FIG. 11, a deep device isolation pattern 150 may be provided in the photoelectric conversion layer 10. The deep device isolation pattern 150 may include an insulating pattern 113 and a semiconductor pattern 115. The deep device isolation pattern 150 may include a horizontal portion parallel to the first surface 100a of the substrate 100 and a vertical portion disposed in the vertical trench BTR extending from the horizontal portion toward the first surface 100a of the substrate 100.

The vertical portion of the deep device isolation pattern 150 may be filled with the insulating pattern 113, and the horizontal portion of the deep device isolation pattern 150 may include the semiconductor pattern 115 and the insulating pattern 113. In this case, the semiconductor pattern 115 may not extend into the inside of the substrate 100 and may be disposed only on the second surface 100b of the substrate 100. That is, the semiconductor pattern 115 may be defined as the horizontal portion 115H of the semiconductor pattern 115.

A depth of the vertical portions of the deep device isolation pattern 150 may all be the same. That is, a depth of the vertical trenches BTR may all be the same.

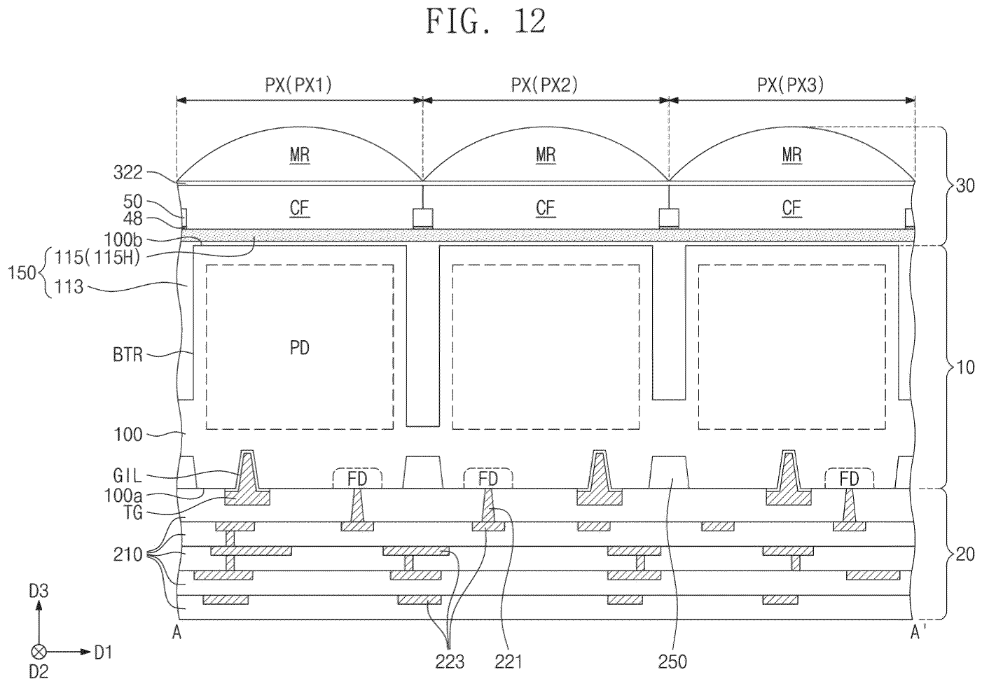

FIG. 12 is a cross-sectional view for explaining an image sensor according to embodiments, and corresponds to a cross-section taken along line A-A′ in FIG. 3. To simplify the explanation, content that overlaps with the above-described content is omitted.

Referring to FIG. 12, a deep device isolation pattern 150 may be provided in the photoelectric conversion layer 10. The deep device isolation pattern 150 may include a horizontal portion parallel to the first surface 100a of the substrate 100 and a vertical portion disposed in the vertical trench BTR extending from the horizontal portion toward the first surface 100a of the substrate 100.

The vertical portion of the deep device isolation pattern 150 may be filled with the insulating pattern 113, and the horizontal portion of the deep device isolation pattern 150 may include the semiconductor pattern 115 and the insulating pattern 113. In this case, the semiconductor pattern 115 may not extend into the inside of the substrate 100 and may be disposed only on the second surface 100b of the substrate 100. That is, the semiconductor pattern 115 may be defined as the horizontal portion 115H of the semiconductor pattern 115.

A depth of the vertical portions of the deep device isolation pattern 150 may be different. That is, depths of the vertical trenches BTR may be different.

A depth of one vertical portion may be greater than a depth of another vertical portion. In the plurality of deep device isolation patterns 150, distances from the additional separation pattern 250 to the deep device isolation patterns 150 may be different.

In the image sensor according to embodiments, the trench may be formed perpendicular to the substrate to form the deep device isolation pattern, thereby reducing the bowing of the deep device isolation pattern and the void in the deep device isolation pattern. As a result, the reliability of the image sensor may be improved.

In some embodiments, each of the components represented by a block as illustrated in FIG. 1 may be implemented as various numbers of hardware and/or firmware structures that execute respective functions described above, according to example embodiments. For example, at least one of these components may include various hardware components including a digital circuit, a programmable or non-programmable logic device or array, an application specific integrated circuit (ASIC), transistors, capacitors, logic gates, or other circuitry using use a direct circuit structure, such as a memory, a processor, a logic circuit, a look-up table, etc., that may execute the respective functions through controls of one or more microprocessors or other control apparatuses. Also, at least one of these components may further include or may be implemented by a processor such as a central processing unit (CPU) that performs the respective functions, a microprocessor, or the like. Functional aspects of example embodiments may be implemented in algorithms that execute on one or more processors. Furthermore, the components, elements, modules or units represented by a block or processing steps may employ any number of related art techniques for electronics configuration, signal processing and/or control, data processing and the like.

While aspects of embodiments have been particularly shown and described, it will be understood that various changes in form and details may be made therein without departing from the spirit and scope of the following claims.

What is claimed is:

1. An image sensor comprising:
a substrate comprising a first surface, a second surface and a plurality of pixel regions between the first surface and the second surface;
a gate electrode on the first surface;
a photoelectric conversion region in a pixel region among the plurality of pixel regions; and
a deep device isolation pattern extending around the pixel region,
wherein the deep device isolation pattern comprises a horizontal portion parallel to the first surface of the substrate and a vertical portion extending from the horizontal portion toward the first surface of the substrate,
wherein the vertical portion of the deep device isolation pattern comprises:
a lowermost portion at a lowermost surface of the vertical portion;
an uppermost portion at an uppermost surface of the vertical portion;
a central portion between the lowermost portion and the uppermost portion;
a lower middle portion between the lowermost portion and the central portion; and
an upper middle portion between the uppermost portion and the central portion,
wherein a ratio of a width of the uppermost portion to a width of the central portion is between 1:0.9 and 1:1.1, and
wherein the deep device isolation pattern is spaced apart from the first surface of the substrate.

2. The image sensor of claim 1, further comprising an additional separation pattern on the first surface of the substrate, wherein the additional separation pattern is spaced apart from the deep device isolation pattern, and vertically overlaps the deep device isolation pattern.

3. The image sensor of claim 1, wherein the deep device isolation pattern comprises:
a semiconductor pattern; and
an insulating pattern between the semiconductor pattern and the substrate.

4. The image sensor of claim 1, wherein the vertical portion of the deep device isolation pattern comprises:
a first vertical portion; and
a second vertical portion adjacent to and spaced apart from the first vertical portion, and
wherein lowermost surfaces of the first vertical portion and the second vertical portion are provided at different levels.

5. The image sensor of claim 4, wherein a ratio of a length of the first vertical portion of the deep device isolation pattern to a length of the second vertical portion is 1:0.8.

6. The image sensor of claim 1, further comprising:
a light shielding pattern on the horizontal portion of the deep device isolation pattern, and
a low refractive pattern on the light shielding pattern,
wherein the light shielding pattern and the low refractive pattern have a grid structure between light transmission regions that vertically overlap each of the plurality of pixel regions.

7. The image sensor of claim 1, wherein a ratio of a width of the uppermost portion to a width of the upper middle portion is between 1:1 and 1:1.15.

8. The image sensor of claim 1, wherein the vertical portion of the deep device isolation pattern comprises:
a first vertical portion; and
a second vertical portion adjacent to and spaced apart from the first vertical portion, and
wherein one microlens is between the first vertical portion and the second vertical portion in a plan view.

9. The image sensor of claim 1, further comprising wirings provided in an interlayer insulating layer on the first surface and electrically connected to the gate electrode.

10. An image sensor comprising:
a substrate comprising a first surface in contact with a gate electrode, a second surface facing the first surface and a plurality of pixel regions;
a photoelectric conversion region in a pixel region among the plurality of pixel regions; and
a deep device isolation pattern extending around the pixel region,
wherein the deep device isolation pattern comprises:
a horizontal portion parallel to the first surface of the substrate; and
a vertical portion in a vertical trench extending from the horizontal portion toward the first surface of the substrate,
wherein a sidewall of the vertical trench is perpendicular to the first surface of the substrate, and
wherein a depth of the vertical trench is less than a thickness of the substrate.

11. The image sensor of claim 10, further comprising an additional separation pattern on the first surface of the substrate that is spaced apart from the deep device isolation pattern.

12. The image sensor of claim 11, wherein a sidewall of the deep device isolation pattern is perpendicular to the first surface of the substrate, and
wherein a sidewall of the additional separation pattern is inclined with respect to the first surface of the substrate.

13. The image sensor of claim 10, further comprising:
a light shielding pattern provided on the horizontal portion of the deep device isolation pattern, and
a low refractive pattern on the light shielding pattern,
wherein the vertical portion vertically overlaps the light shielding pattern.

14. The image sensor of claim 10, wherein the vertical portion of the deep device isolation pattern comprises:
a first vertical portion; and
a second vertical portion adjacent to and spaced apart from the first vertical portion, and
wherein a distance between a lowermost surface of the first vertical portion and the first surface of the substrate is less than a distance between the first surface of the substrate and a lowermost surface of the second vertical portion.

15. The image sensor of claim 10, wherein the deep device isolation pattern comprises:
a semiconductor pattern; and
an insulating pattern interposed between the semiconductor pattern and the substrate.

16. The image sensor of claim 15, wherein the vertical portion of the deep device isolation pattern is filled with the insulating pattern, and the horizontal portion of the deep device isolation pattern comprises the semiconductor pattern and the insulating pattern.

17. An image sensor comprising:
a substrate comprising a first surface, a second surface and a plurality of pixel regions between the first surface and the second surface;
a gate electrode on the first surface of the substrate and extending into the substrate;
a photoelectric conversion region in a pixel region among the plurality of pixel regions;
a floating diffusion region in the pixel region that is spaced apart from the photoelectric conversion region; and
a deep device isolation pattern extending around the pixel region,
wherein the deep device isolation pattern comprises:
a horizontal portion parallel to the first surface of the substrate; and
a vertical portion in the vertical trench extending from the horizontal portion toward the first surface of the substrate,
wherein the vertical portion of the deep device isolation pattern comprises:
a lowermost portion at a lowermost surface of the vertical portion;
an uppermost portion at an uppermost surface of the vertical portion;
a central portion between the lowermost portion and the uppermost portion;
a lower middle portion between the lowermost portion and the central portion; and
an upper middle portion between the uppermost portion and the central portion,
wherein a ratio of a width of the uppermost portion to a width of the central portion is between 1:0.9 and 1:1.1, and
wherein the deep device isolation pattern is spaced apart from the first surface of the substrate.

18. The image sensor of claim 17, further comprising:
a light shielding pattern provided on the horizontal portion of the deep device isolation pattern;
low refractive patterns on the light shielding pattern; and
a color filter between two of the low refractive patterns.

19. The image sensor of claim 17, further comprising wirings provided in an interlayer insulating layer on the first surface and electrically connected to the gate electrode and the floating diffusion region.

20. The image sensor of claim 17, further comprising an additional separation pattern on the first surface of the substrate that is spaced apart from the deep device isolation pattern.
